(19) United States
(12) Patent Application Publication
(10) Pub. No.: US 2010/0003805 A1
(43) Pub. Date: Jan. 7, 2010

(54) SEMICONDUCTOR DEVICE FABRICATION METHOD

(75) Inventor: Kazuhisa Arai, Ota-Ku (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/487,436

(22) Filed: Jun. 18, 2009

(30) Foreign Application Priority Data
Jul. 2, 2008 (JP) 2008-173670

(51) Int. Cl. H01L 21/78

(52) U.S. Cl. 438/460; 257/E21.599

(57) ABSTRACT

A semiconductor device fabrication method for dividing a semiconductor wafer into individual devices along a plurality of streets. The method includes a masking step of attaching a mask member having a plurality of openings to the back side of the semiconductor wafer, the openings respectively corresponding to the devices formed on the front side of the semiconductor wafer, an electrode forming step of forming a metal layer on the back side of the semiconductor wafer after performing the masking step to thereby form a plurality of electrodes on the back side of the semiconductor wafer so that the electrodes respectively correspond to the devices formed on the front side of the semiconductor wafer, a mask member stripping step of stripping the mask member from the back side of the semiconductor wafer, a modified layer forming step of applying a laser beam having a transmission wavelength to the semiconductor wafer along the streets, thereby forming a modified layer in the semiconductor wafer along each street, and a dividing step of applying an external force to the semiconductor wafer, thereby dividing the semiconductor wafer along each street.

### BACKGROUND OF THE INVENTION

1. Field of the Invention

The present invention relates to a semiconductor device fabrication method for dividing a semiconductor wafer into individual devices along a plurality of crossing streets formed on the front side of the semiconductor wafer, wherein the devices are respectively formed in a plurality of regions partitioned by the streets.

2. Description of the Related Art

In a semiconductor device fabrication process, a plurality of crossing streets (division lines) are formed on the front side of a substantially disk-shaped semiconductor substrate to partition a plurality of regions where devices such as ICs, LSIs, and IGBTs (insulated gate bipolar transistors) are respectively formed. A metal layer as an electrode is formed on the back side of each semiconductor device such as an insulated gate bipolar transistor. A semiconductor wafer having devices such as insulated gate bipolar transistors formed on the front side of a semiconductor substrate is cut along each street after forming a metal layer on the back side of the semiconductor substrate, thereby dividing the semiconductor wafer into the individual devices (see Japanese Patent Laid-open No. Hei 10-92778, for example).

Cutting of a wafer such as a semiconductor wafer along each street is usually performed by a cutting apparatus called a dicer. This cutting apparatus includes a chuck table for holding a wafer such as a semiconductor wafer, cutting means for cutting the wafer as a workpiece held on the chuck table, and feeding means for relatively moving the chuck table and the cutting means. The cutting means includes a rotating spindle, a cutting blade mounted on the rotating spindle, and a driving mechanism for rotationally driving the rotating spindle. The cutting blade is composed of a circular base and an annular cutting edge mounted on the outer circumferential portion of one side surface of the base. The cutting edge is formed by fixing diamond abrasive grains having a grain size of about 3 μm, for example, to the base by electroforming so as to obtain a thickness of about 20 to 30 μm.

Thus, the cutting edge of the cutting blade has a thickness of about 20 to 30 μm, so that each street partitioning the adjacent devices must have a width of about 50 μm. Accordingly, in the case that the size of each device formed on a semiconductor substrate is small, the ratio of the area of the streets to the area of the devices is large, causing a reduction in productivity.

As a method of dividing a platelike workpiece such as a semiconductor wafer, a laser processing method using a pulsed laser beam having a transmission wavelength to the workpiece has been proposed in recent years. In this laser processing method, the pulsed laser beam is applied to the workpiece along the streets in the condition where the focal point of the pulsed laser beam is set inside the workpiece in a subject area to be divided. In such a dividing method using laser processing, the pulsed laser beam having a transmission wavelength to the workpiece is applied to the workpiece from one side thereof in the condition where the focal point is set inside the workpiece, thereby continuously forming a modified layer inside the workpiece along each street. By forming the modified layer along each street, the strength of the workpiece along the modified layer is reduced. Accordingly, by applying an external force to the workpiece along each street, the workpiece can be divided along each street (see Japanese Patent No. 3408805, for example).

In forming such a modified layer along each street inside a semiconductor substrate constituting a semiconductor wafer, it is preferable to apply a laser beam having a transmission wavelength to the semiconductor substrate from the back side of the semiconductor substrate in the condition where the focal point of the laser beam is set inside the semiconductor substrate. However, in a semiconductor wafer having a metal layer as electrodes formed on the back side of the semiconductor substrate, the laser beam cannot be applied through the metal layer in the condition where the focal point is set inside the semiconductor substrate. Accordingly, it is necessary to partially remove the metal layer formed on the back side of the semiconductor substrate along each street by using a cutting apparatus or the like, causing a reduction in productivity.

Further, even if the laser beam having a transmission wavelength to the semiconductor substrate is applied from the front side of the semiconductor substrate in the condition where the focal point is set inside the semiconductor substrate to thereby form a modified layer along each street inside the semiconductor substrate, the metal layer as the electrodes formed on the back side of the semiconductor substrate cannot be accurately broken along each street by applying an external force to the semiconductor substrate along each street.

### SUMMARY OF THE INVENTION

It is therefore an object of the present invention to provide a semiconductor device fabrication method which can form electrodes on the back side of a semiconductor substrate so that the electrodes respectively correspond to devices formed on the front side of the semiconductor substrate, can form a modified layer inside the semiconductor substrate by applying a laser beam to the semiconductor substrate along each street so that the focal point of the laser beam is set inside the semiconductor substrate, and can divide the semiconductor substrate into the individual devices along each street where the modified layer is formed.

In accordance with an aspect of the present invention, there is provided a semiconductor device fabrication method for dividing a semiconductor wafer into individual devices along a plurality of crossing streets formed on the front side of the semiconductor wafer, wherein the devices are respectively formed in a plurality of regions partitioned by the streets, the semiconductor device fabrication method including a masking step of attaching a mask member having a plurality of openings to the back side of the semiconductor wafer, the openings of the mask member respectively corresponding to the devices formed on the front side of the semiconductor wafer; an electrode forming step of forming a metal layer on the back side of the semiconductor wafer after performing the masking step to thereby form a plurality of electrodes on the back side of the semiconductor wafer so that the electrodes respectively correspond to the devices formed on the front side of the semiconductor wafer; a mask member stripping step of stripping the mask member from the back side of the semiconductor wafer after performing the electrode forming step; a modified layer forming step of applying a laser beam having a transmission wavelength to the semiconductor wafer along the streets after performing the mask member stripping step, thereby forming a modified layer in the semiconductor wafer along each street; and a dividing step of applying an external force to the semiconductor wafer after performing the modified layer forming step, thereby dividing the semiconductor wafer along each street.

Preferably, the laser beam is applied from the back side of the semiconductor wafer in the modified layer forming step.

In the semiconductor device fabrication method according to the present invention, the mask member is first attached to the back side of the semiconductor wafer so that the openings of the mask member respectively correspond to the devices formed on the front side of the semiconductor wafer. Thereafter, the metal layer is formed on the back side of the semiconductor wafer so as to cover the mask member, thereby forming the electrodes respectively corresponding to the devices formed on the front side of the semiconductor wafer. Accordingly, the electrodes can be accurately formed on the back side of the respective devices. Further, the electrodes formed on the back side of the semiconductor wafer are not formed in the region where the streets are formed. Accordingly, the laser beam can be applied from the back side of the semiconductor wafer, and the electrodes have no interference in the dividing step of dividing the semiconductor wafer along each street where the modified layer is formed.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a semiconductor wafer to be divided into individual devices by the semiconductor device fabrication method according to the present invention;

FIG. 2 is a perspective view showing a condition where a protective tape is attached to the front side of the semiconductor wafer shown in FIG. 1;

FIGS. 3A and 3B are perspective views for illustrating a masking step in the semiconductor device fabrication method according to the present invention;

FIG. 4 is a schematic sectional view of a sputtering apparatus for performing an electrode forming step in the semiconductor device fabrication method according to the present invention;

FIG. 5 is an enlarged sectional view of the semiconductor wafer processed by the electrode forming step using the sputtering apparatus shown in FIG. 4;

FIG. 6 is a perspective view for illustrating a mask member stripping step in the semiconductor device fabrication method according to the present invention;

FIG. 7 is a perspective view of an essential part of a laser processing apparatus for performing a modified layer forming step in the semiconductor device fabrication method according to the present invention;

FIGS. 8A and 8B are sectional side views for illustrating the modified layer forming step using the laser processing apparatus shown in FIG. 7;

FIG. 9 is a perspective view for illustrating a wafer supporting step and a protective tape peeling step in the semiconductor device fabrication method according to the present invention;

FIG. 10 is a perspective view of a wafer dividing apparatus for performing a dividing step in the semiconductor device fabrication method according to the present invention;

FIGS. 11A and 11B are schematic sectional views for illustrating the dividing step using the wafer dividing apparatus shown in FIG. 10; and

FIG. 12 is a schematic sectional view for illustrating a pickup step in the semiconductor device fabrication method according to the present invention.

### DETAILED DESCRIPTION OF THE PREFERRED EMBODIMENT

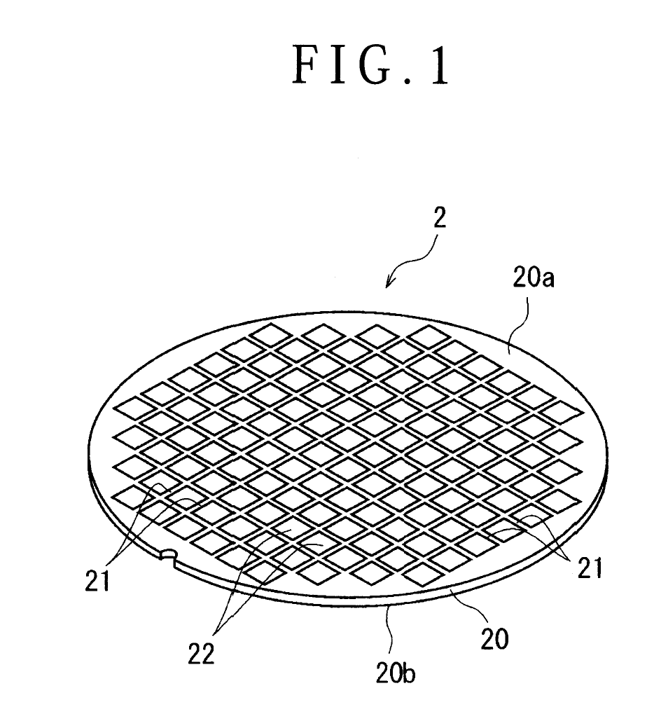

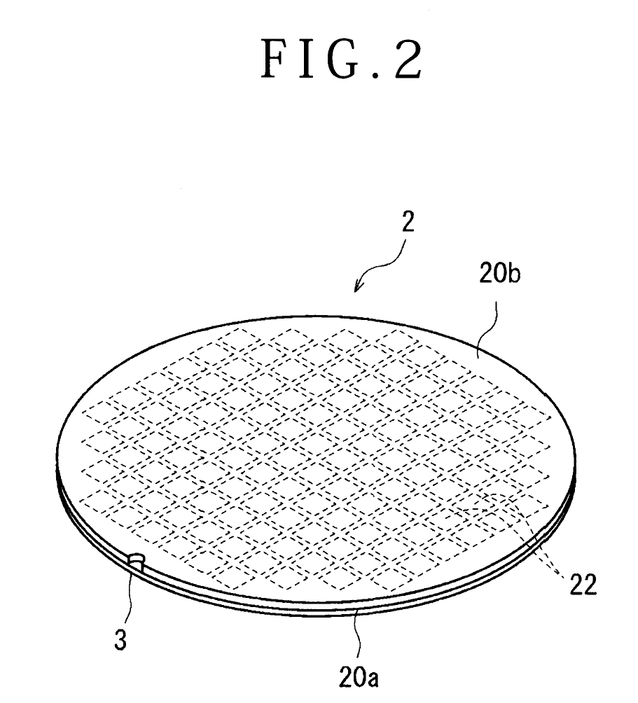

A preferred embodiment of the semiconductor device fabrication method according to the present invention will now be described in detail with reference to the attached drawings. FIG. 1 is a perspective view of a semiconductor wafer 2 to be divided into individual devices by the semiconductor device fabrication method according to the present invention. The semiconductor wafer 2 shown in FIG. 1 is formed from a semiconductor substrate 20 such as a silicon substrate having a thickness of 100 μm, for example. The semiconductor substrate 20 has a front side 20a and a back side 20b. The front side 20a of the semiconductor substrate 20 is formed with a plurality of crossing streets 21 to thereby partition a plurality of rectangular regions arranged like a matrix, and a plurality of devices 22 such as insulated gate bipolar transistors are formed in these rectangular regions. As shown in FIG. 2, a protective tape 3 is attached to the front side 20a of the substrate 20 constituting the semiconductor wafer 2, so as to protect the devices 22 formed on the front side 20a (protective tape attaching step).

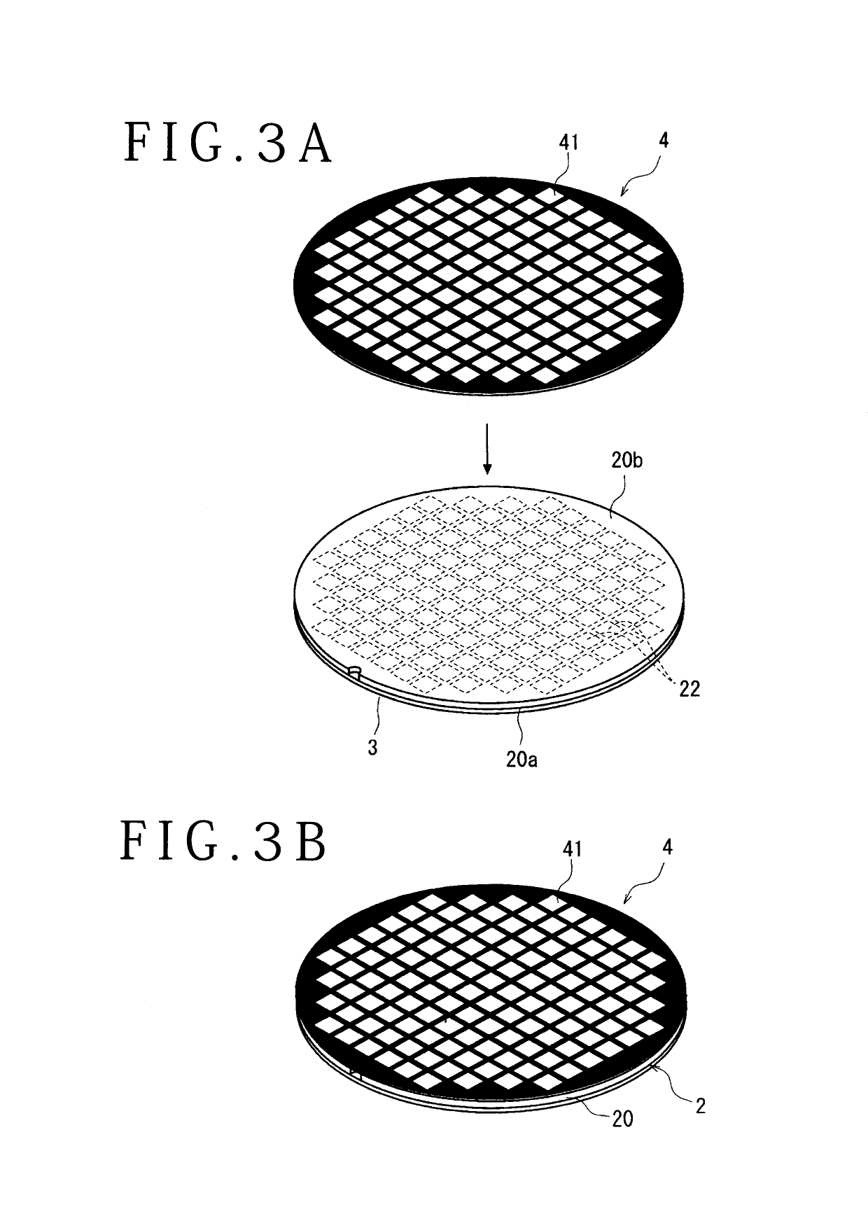

As shown in FIGS. 3A and 3B, a masking step is next performed in such a manner that a mask member 4 having a plurality of openings 41 respectively corresponding to the plural devices 22 formed on the front side 20a of the semiconductor substrate 20 constituting the semiconductor wafer 2 is attached to the back side 20b of the semiconductor substrate 20. The mask member 4 is formed from a suitable resin sheet, and it has the plural openings 41 formed by punching a region of the resin sheet corresponding to a region of the semiconductor substrate 20 where the plural devices 22 are formed on the front side 20a of the semiconductor substrate 20. The back side of the mask member 4 is coated with an adhesive material, so that the mask member 4 is attached through the adhesive material to the back side 20b of the semiconductor substrate 20. As a modification, the masking step may be performed by forming a photoresist film on the back side 20b of the semiconductor substrate 20 and next exposing an electrode forming region of the photoresist film to light to thereby form a plurality of openings in this electrode forming region.

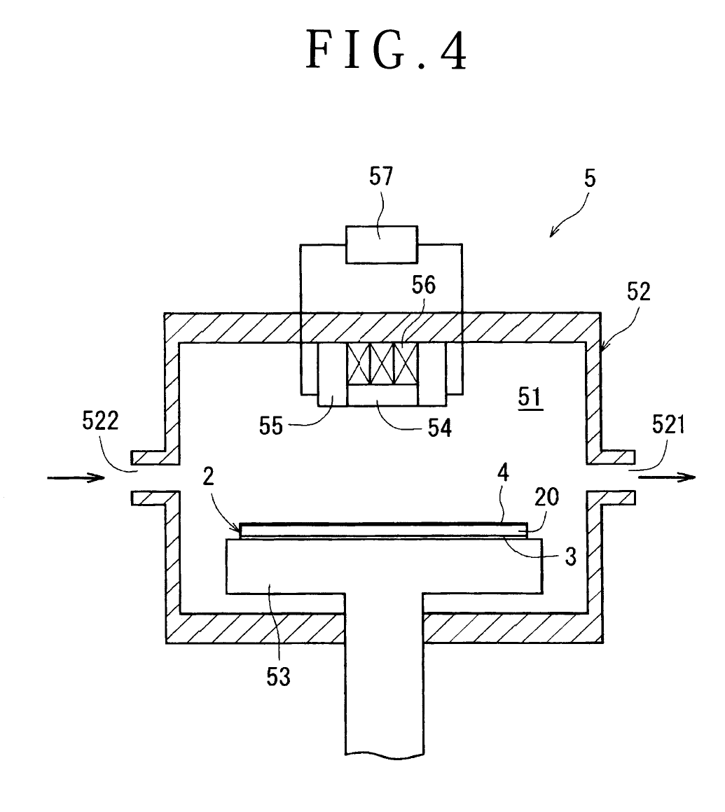

After performing the masking step, an electrode forming step is performed in such a manner that a metal layer is formed on the back side 20b of the semiconductor substrate 20 constituting the semiconductor wafer 2 to thereby form a plurality of electrodes on the back side 20b of the semiconductor substrate 20 respectively corresponding to the plural devices 22 formed on the front side 20a of the semiconductor substrate 20. This electrode forming step is performed by using a sputtering apparatus 5 shown in FIG. 4. As shown in FIG. 4, the sputtering apparatus 5 includes a housing 52 defining a sputter chamber 51, an electrostatic chuck type holding table 53 as an anode provided in the sputter chamber 51 of the housing 52 for holding the semiconductor wafer 2 as a workpiece, a cathode 55 provided in the sputter chamber 51 so as to be opposed to the holding table 53 for mounting a target 54 of metal (e.g., titanium, nickel, or gold) to be deposited to the workpiece, exciting means 56 for exciting the target 54, and a high-frequency power supply 57 for applying a high-frequency voltage to the cathode 55. The housing 52 is formed with an evacuation hole 521 for making the communication between the sputter chamber 51 and evacuating means (not shown) and a gas inlet 522 for making the communication between the sputter chamber 51 and sputter gas supplying means (not shown).

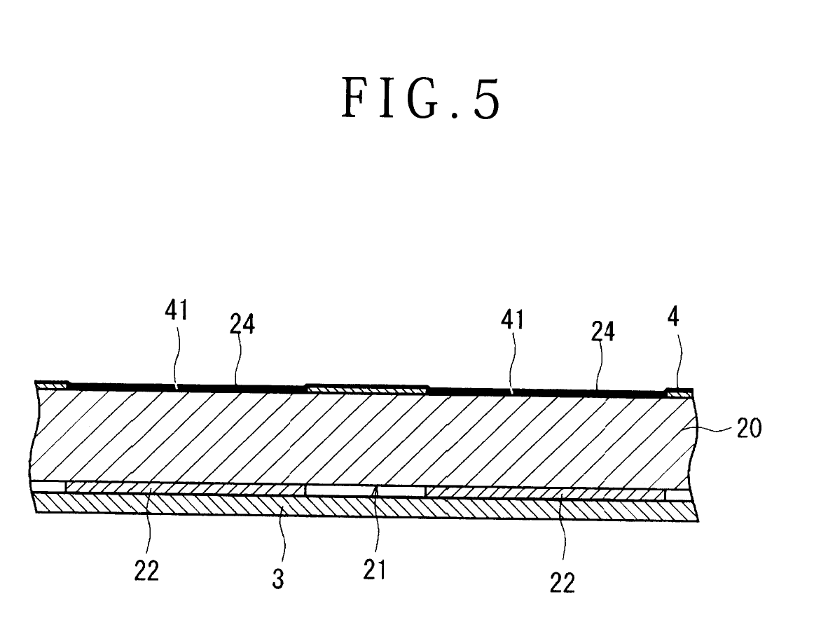

The electrode forming step using the sputtering apparatus 5 is performed in the following manner. The semiconductor wafer 2 with the mask member 4 obtained by the masking step mentioned above is electrostatically held on the holding table 53 in the condition where the protective tape 3 attached to the front side 20a of the semiconductor substrate 20 constituting the semiconductor wafer 2 is placed on the holding table 53, so that the mask member 4 attached to the back side 20b of the semiconductor substrate 20 is oriented upward so as to be opposed to the target 54. Thereafter, the exciting means 56 is operated to excite the target 54, and a high-frequency voltage having a frequency of about 40 kHz is applied from the high-frequency power supply 57 to the cathode 55. The evacuating means (not shown) is operated to evacuate the sputter chamber 51 to about 10⁻² to 10⁻⁴ Pa, and the sputter gas supplying means (not shown) is operated to introduce an argon gas into the sputter chamber 51 to generate a plasma. Accordingly, argon ions in the plasma collide with the target 54 of metal mounted on the cathode 55 to thereby eject metal particles from the surface of the target 54. The metal particles thus ejected from the target 54 are deposited to the back side 20b of the semiconductor substrate 20 constituting the semiconductor wafer 2. That is, the metal particles are deposited to the mask member 4 attached to the back side 20b of the semiconductor substrate 20 and to the electrode forming region exposed to the plural openings 41 of the mask member 4 on the back side 20b of the semiconductor substrate 20 corresponding to the device forming region where the devices 22 are formed on the front side 20a of the semiconductor substrate 20. As a result, a metal layer is formed on the back side 20b of the semiconductor substrate 20 through the mask member 4, so that a plurality of electrodes 24 are formed on the back side 20b of the semiconductor substrate 20 so as to respectively correspond to the plural devices 22 formed on the front side 20a of the semiconductor substrate 20 as shown in FIG. 5.

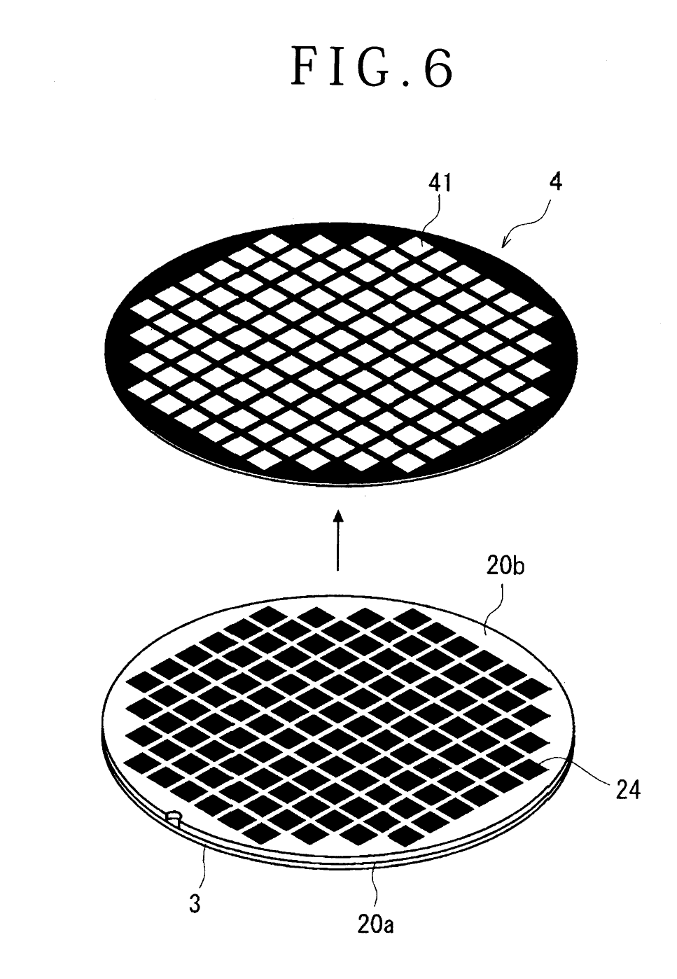

After performing the electrode forming step, a mask member stripping step is performed to strip the mask member 4 from the back side 20b of the semiconductor substrate 20 constituting the semiconductor wafer 2 as shown in FIG. 6. As a result, the plural electrodes 24 are formed on the back side 20b of the semiconductor substrate 20 so as to respectively correspond to the plural devices 22 formed on the front side 20a of the semiconductor substrate 20.

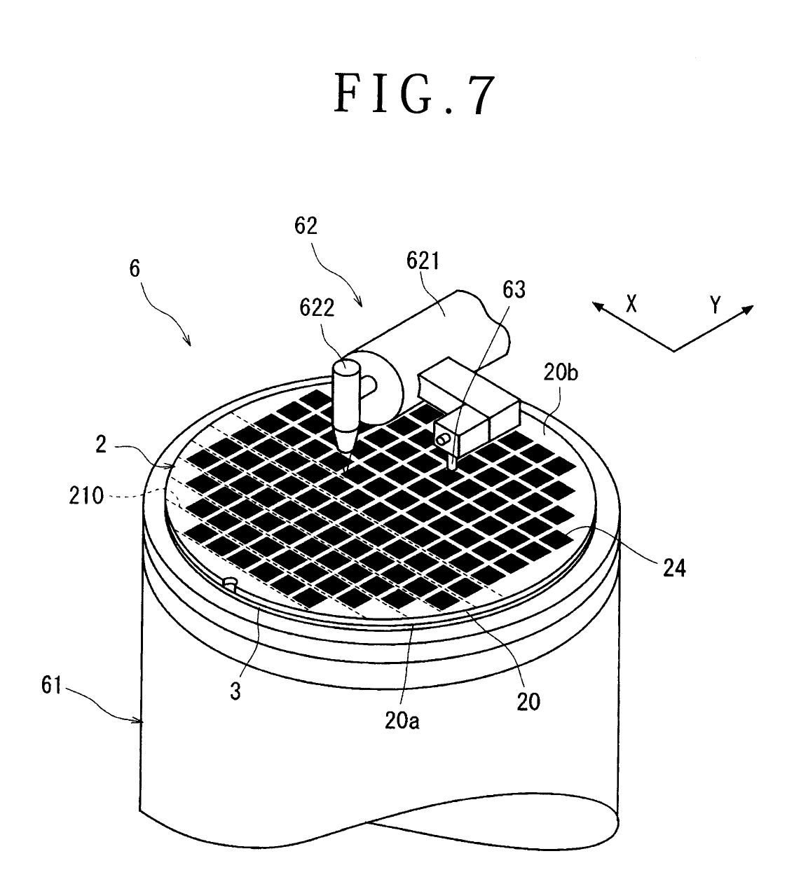

After performing the mask member stripping step, a modified layer forming step is performed in such a manner that a laser beam having a transmission wavelength to the semiconductor substrate 20 constituting the semiconductor wafer 2 from which the mask member 4 is stripped is applied along the streets 21 to thereby form a modified layer inside the semiconductor substrate 20 along each street 21. This modified layer forming step is performed by using a laser processing apparatus 6 shown in FIG. 7. As shown in FIG. 7, the laser processing apparatus 6 includes a chuck table 61 for holding the semiconductor wafer 2 as a workpiece, laser beam applying means 62 for applying a laser beam to the semiconductor wafer 2 held on the chuck table 61, and imaging means 63 for imaging the semiconductor wafer 2 held on the chuck table 61. The chuck table 61 is so configured as to hold the semiconductor wafer 2 by using suction means (not shown). The chuck table 61 is movable both in a direction shown by an arrow X in FIG. 7 by feeding means (not shown) and in a direction shown by an arrow Y in FIG. 7 by indexing means (not shown).

The laser beam applying means 62 includes a cylindrical casing 621 extending in a substantially horizontal direction and focusing means 622 mounted on the front end of the casing 621 for applying a pulsed laser beam. The imaging means 63 is mounted on a front end portion of the casing 621, and includes an ordinary imaging means (CCD) for imaging the semiconductor wafer 2 by using visible light, infrared light applying means for applying infrared light to the semiconductor wafer 2, an optical system for capturing the infrared light applied by the infrared light applying means, and an imaging device (infrared CCD) for outputting an electrical signal corresponding to the infrared light captured by the optical system. An image signal output from the imaging means 63 is transmitted to control means (described later).

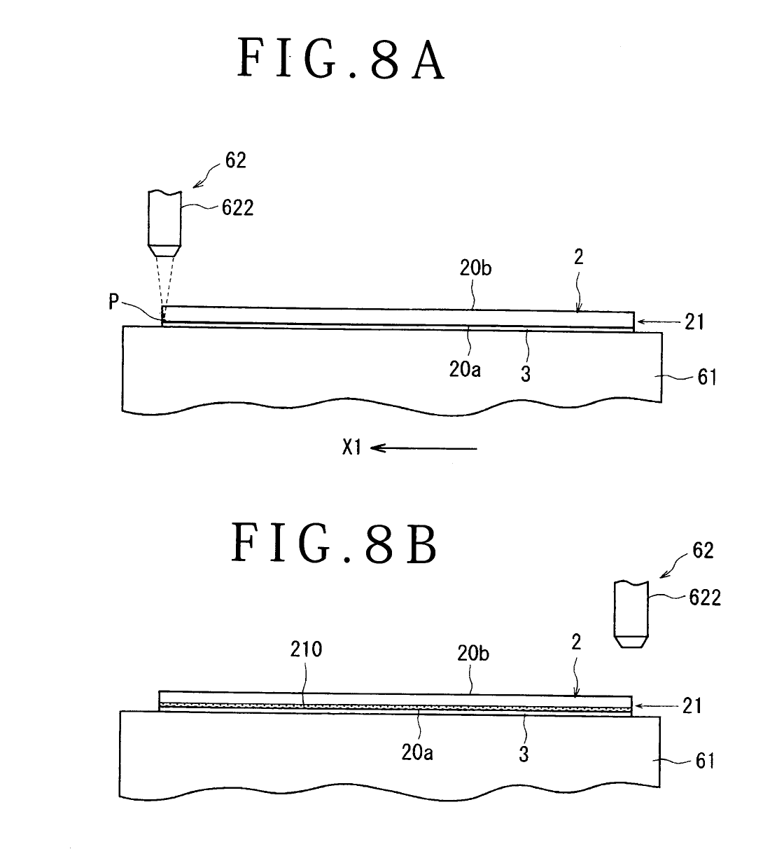

The modified layer forming step using the laser processing apparatus 6 will now be described with reference to FIGS. 7 to 8B. First, the semiconductor wafer 2 obtained by performing the mask member stripping step is placed on the chuck table 61 of the laser processing apparatus 6 in the condition where the protective tape 3 attached to the front side 20a of the semiconductor substrate 20 is in contact with the chuck table 61 as shown in FIG. 7. Thereafter, the suction means (not shown) is operated to hold the semiconductor wafer 2 on the chuck table 61 under suction. Accordingly, the back side 20b of the semiconductor substrate 20 constituting the semiconductor wafer 2 held on the chuck table 61 is oriented upward. Thereafter, the chuck table 61 thus holding the semiconductor wafer 2 under suction is moved to a position directly below the imaging means 63 by the feeding means (not shown).

In the condition where the chuck table 61 is positioned directly below the imaging means 63, an alignment operation is performed by the imaging means 63 and the control means (not shown) to detect a subject area of the semiconductor wafer 2 to be laser-processed along each street 21 formed on the front side 20a of the semiconductor substrate 20. More specifically, the imaging means 63 and the control means (not shown) perform image processing such as pattern matching for making the alignment of the first streets 21 extending in a predetermined direction on the semiconductor substrate 20 and the focusing means 622 of the laser beam applying means 62 for applying the laser beam to the semiconductor substrate 20 along the first streets 21, thus performing the alignment of a laser beam applying position. Similarly, the alignment of a laser beam applying position is performed for the second streets 21 extending in a direction perpendicular to the above-mentioned predetermined direction of the first streets 21 on the semiconductor substrate 20. Although the front side 20a of the semiconductor substrate 20 on which the first and second streets 21 are formed is oriented downward, the first and second streets 21 can be imaged from the back side 20b because the imaging means 63 includes the infrared light applying means, the optical system for capturing infrared light, and the imaging device (infrared CCD) for outputting an electrical signal corresponding to the infrared light as mentioned above. Further, no metal layer is formed in a region of the back side 20b of the semiconductor wafer 2 corresponding to the region of the front side 20a where the streets 21 are formed. Accordingly, this region of the back side 20b where no metal layer is formed may be directly aligned to the focusing means 622.

After performing the alignment operation mentioned above, the chuck table 61 is moved to a laser beam applying area where the focusing means 622 of the laser beam applying means 62 is located as shown in FIG. 8A, thereby positioning one end (left end as viewed in FIG. 8A) of a predetermined one of the first streets 21 directly below the focusing means 622 of the laser beam applying means 62. In this condition, a pulsed laser beam having a transmission wavelength to the semiconductor substrate 20 is applied from the focusing means 622 to the semiconductor substrate 20 along the predetermined first street 21, and the chuck table 61 is moved in a direction shown by an arrow X1 in FIG. 8A at a predetermined feed speed.

When the other end (right end as viewed in FIG. 8B) of the predetermined first street 21 reaches the laser beam applying position of the focusing means 622 of the laser beam applying means 62 as shown in FIG. 8B, the application of the pulsed laser beam is stopped and the movement of the chuck table 61 is also stopped. In the modified layer forming step as above, as shown in FIG. 8A, the focal point P of the pulsed laser beam is set near the front side 20a (lower surface as viewed in FIG. 8A) of the semiconductor substrate 20 constituting the semiconductor wafer 2, so that a modified layer 210 is formed in the semiconductor substrate 20 so as to be exposed to the front side 20a along the predetermined first street 21 as shown in FIG. 8B. This modified layer 210 is formed as a melt rehardened layer.

In the modified layer forming step as described above, the plural electrodes 24 are formed on the side to which the pulse laser beam is applied, that is, on the back side 20b of the semiconductor substrate 20 so as to respectively correspond to the plural devices 22 formed on the front side 20a of the semiconductor substrate 20. That is, the electrodes 24 are not formed in the region of the back side 20b corresponding to the region of the front side 20a where the streets 21 are formed. Accordingly, in the modified layer forming step, the electrodes 24 have no interference with the application of the pulsed laser beam.

For example, the modified layer forming step mentioned above is performed under the following processing conditions.

Light source: LD pumped Q-switched Nd:YVO4 pulsed laser

Wavelength: 1064 nm

Repetition frequency: 100 kHz

Pulse output: 10 μJ

Focused spot diameter: φ1 μm

Work feed speed: 100 mm/sec

The modified layer 210 may be formed in the semiconductor substrate 20 so as not to be exposed to the front side 20a and the back side 20b. Further, the modified layer forming step mentioned above may be repeated plural times in the condition where the focal point P is stepwise changed in depth to thereby form a plurality of modified layers 210 having a multilayer structure. After the above described modified layer forming step is performed, the step is performed to repeat along all the first and second streets 21 formed on the semiconductor substrate 20 constituting the semiconductor wafer 2.

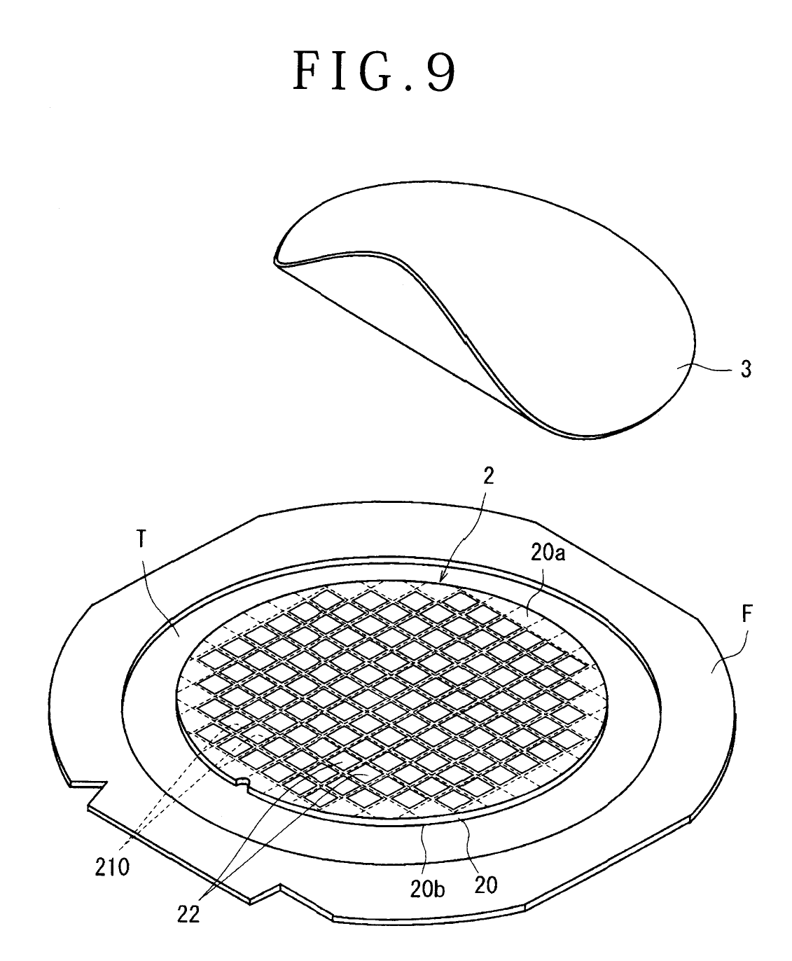

After thus finishing the modified layer forming step along all of the first and second streets 21, a wafer supporting step is performed in such a manner that the semiconductor wafer 2 formed with the modified layer 210 along each street 21 is attached at the back side 20b thereof to an adhesive tape T supported to an annular frame F as shown in FIG. 9. More specifically, the adhesive tape T is preliminarily supported at its outer circumferential portion to the annular frame F in such a manner as to cover an opening of the annular frame F. The back side 20b of the semiconductor substrate 20 is attached to the adhesive tape T in the condition where the front side 20a of the semiconductor substrate 20 is oriented upward. Thereafter, the protective tape 3 is peeled off from the front side 20a of the semiconductor substrate 20 (protective tape peeling step).

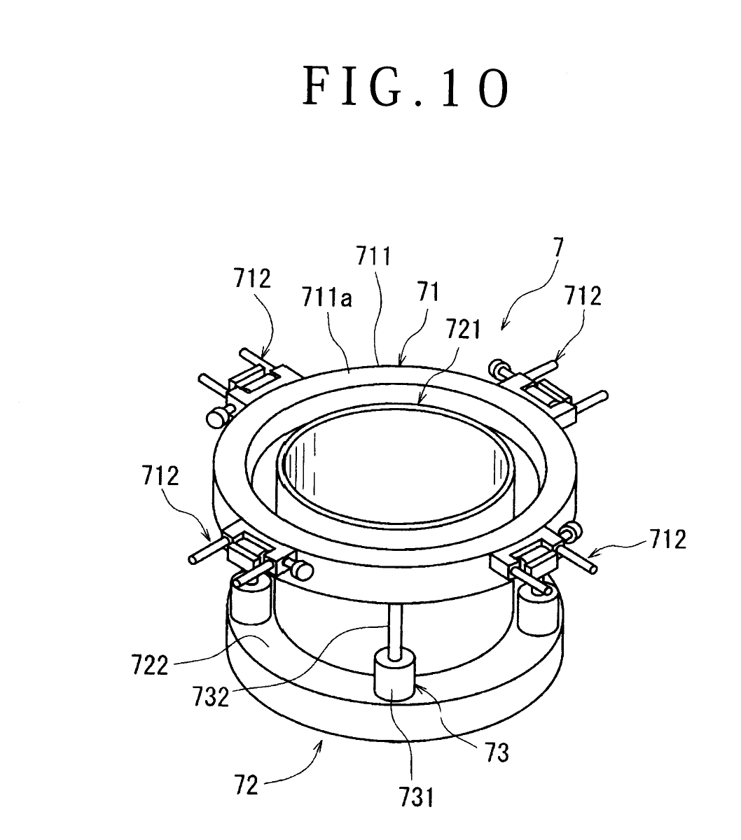

After performing the wafer supporting step including the protective tape peeling step mentioned above, a dividing step is performed in such a manner that an external force is applied to the semiconductor substrate 20 formed with the modified layer 210 along each street 21, thereby dividing the semiconductor substrate 20 along each street 21. This dividing step is performed by using a wafer dividing apparatus 7 shown in FIG. 10. As shown in FIG. 10, the wafer dividing apparatus 7 includes frame holding means 71 for holding the annular frame F and tape expanding means 72 for expanding the adhesive tape T supported to the annular frame F held by the frame holding means 71. The frame holding means 71 includes an annular frame holding member 711 and a plurality of clamps 712 as fixing means provided on the outer circumference of the frame holding member 711. The upper surface of the frame holding member 711 functions as a mounting surface 711a for mounting the annular frame F thereon. The annular frame F mounted on the mounting surface 711a is fixed to the frame holding member 711 by the clamps 712. The frame holding means 71 thus configured is supported by the tape expanding means 72 so as to be vertically movable.

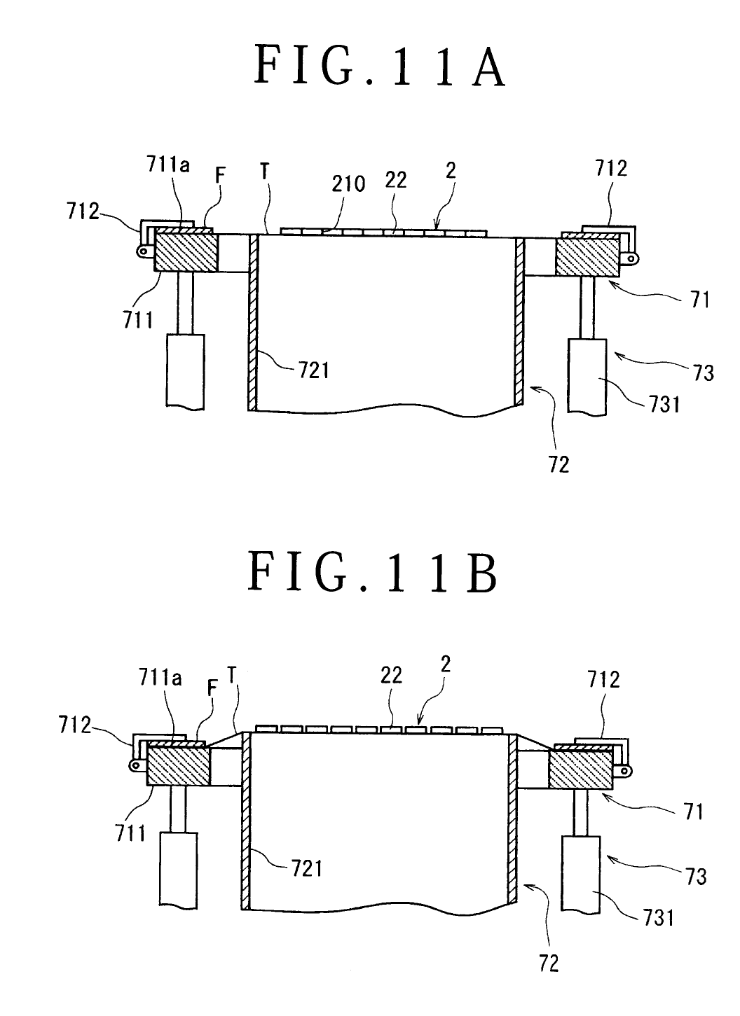

The tape expanding means 72 includes a cylindrical expanding drum 721 as a pressure member provided inside of the annular frame holding member 711. The expanding drum 721 has an outer diameter smaller than the inner diameter of the annular frame F and an inner diameter larger than the outer diameter of the semiconductor wafer 2 attached to the adhesive tape T supported to the annular frame F. The expanding drum 721 has a supporting flange 722 at the lower end thereof. The tape expanding means 72 further includes supporting means 73 for vertically moving the annular frame holding member 711. The supporting means 73 is composed of a plurality of air cylinders 731 provided on the supporting flange 722. Each air cylinder 731 is provided with a piston rod 732 connected to the lower surface of the annular frame holding member 711. The supporting means 73 composed of the plural air cylinders 731 functions to vertically move the annular frame holding member 711 so as to selectively take a reference position where the mounting surface 711a is substantially equal in height to the upper end of the expanding drum 721 as shown in FIG. 11A and an expansion position where the mounting surface 711a is lower in height than the upper end of the expanding drum 721 by a predetermined amount as shown in FIG. 11B. Accordingly, the supporting means 73 composed of the plural air cylinders 731 functions as expansion moving means for relatively moving the expanding drum 721 and the frame holding member 711 in the vertical direction.

The dividing step using the wafer dividing apparatus 7 will now be described with reference to FIGS. 11A and 11B. As shown in FIG. 11A, the annular frame F supporting the semiconductor wafer 2 through the adhesive tape T (i.e., the back side 20b of the semiconductor substrate 20 formed with the modified layer 210 extending along each street 21 on the front side 20a of the semiconductor substrate 20 is attached to the adhesive tape T) is mounted on the mounting surface 711a of the frame holding member 711 constituting the frame holding means 71 and fixed to the frame holding member 711 by the clamps 712. At this time, the frame holding member 711 is set at the reference position shown in FIG. 11A. Thereafter, the air cylinders 731 as the supporting means 73 constituting the tape expanding means 72 are operated to lower the frame holding member 711 to the expansion position shown in FIG. 11B.

Accordingly, the annular frame F fixed to the mounting surface 711a of the frame holding member 711 is also lowered, so that the adhesive tape T supported to the annular frame F comes into abutment in its annular area between the outer circumference of the semiconductor wafer 2 and the inner circumference of the annular frame F against the upper end of the cylindrical expanding drum 721 as a pressure member and is therefore expanded substantially in the radial direction of the expanding drum 721 as shown in FIG. 11B. As a result, a tensile force is radially applied to the semiconductor wafer 2 attached to the adhesive tape T, and the semiconductor substrate 20 constituting the semiconductor wafer 2 is therefore broken along each street 21 where the strength of the semiconductor substrate 20 is lowered because of the presence of the modified layer 210 formed along each street 21, thereby dividing the semiconductor wafer 2 into the individual devices 22. At this time, the plural electrodes 24 formed on the back side 20b of the semiconductor substrate 20 are also separated from each other so as to respectively correspond to the individual devices 22. However, the plural electrodes 24 are not formed in the region where all the streets 21 are formed. Accordingly, the semiconductor wafer 2 can be accurately divided into the individual devices 22 without the interference with the metal layers.

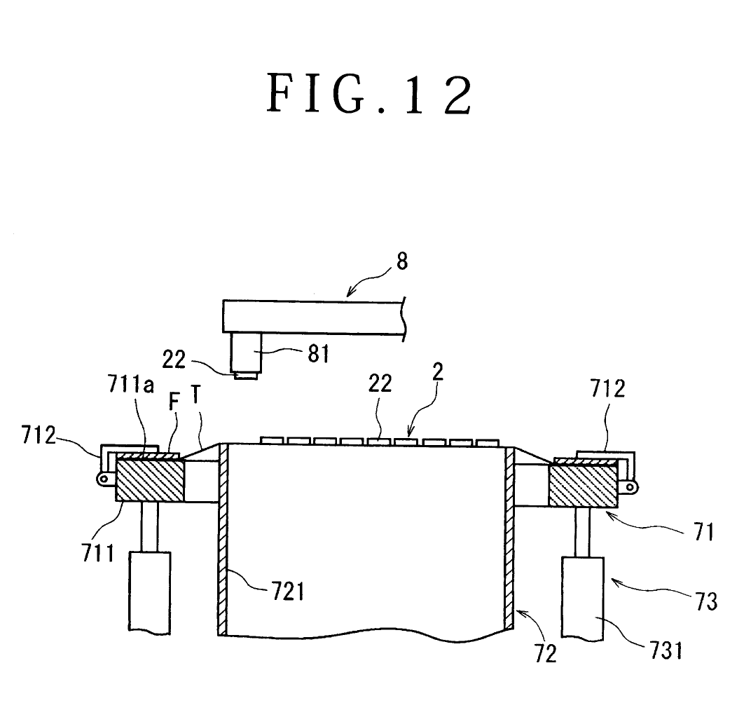

After performing the dividing step mentioned above, a pickup step is performed as shown in FIG. 12 in such a manner that a pickup mechanism 8 having a pickup collet 81 is operated to pick up each device 22 by using the pickup collet 81 from the given position on the adhesive tape T (pickup step). Each device 22 thus held by the pickup collet 81 is transported to a tray (not shown) or a die bonding step.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A semiconductor device fabrication method for dividing a semiconductor wafer into individual devices along a plurality of crossing streets formed on the front side of said semiconductor wafer, wherein said devices are respectively formed in a plurality of regions partitioned by said streets, said semiconductor device fabrication method comprising:
a masking step of attaching a mask member having a plurality of openings to the back side of said semiconductor wafer, said openings respectively corresponding to said devices formed on the front side of said semiconductor wafer;
an electrode forming step of forming a metal layer on the back side of said semiconductor wafer after performing said masking step to thereby form a plurality of electrodes on the back side of said semiconductor wafer so that said electrodes respectively correspond to said devices formed on the front side of said semiconductor wafer;
a mask member stripping step of stripping said mask member from the back side of said semiconductor wafer after performing said electrode forming step;
a modified layer forming step of applying a laser beam having a transmission wavelength to said semiconductor wafer along said streets after performing said mask member stripping step, thereby forming a modified layer in said semiconductor wafer along each street; and
a dividing step of applying an external force to said semiconductor wafer after performing said modified layer forming step, thereby dividing said semiconductor wafer along each street.

2. The semiconductor device fabrication method according to claim 1, wherein said laser beam is applied from the back side of said semiconductor wafer in said modified layer forming step.
